(19) United States
(12) Patent Application Publication
(10) Pub. No.: US 2024/0088869 A1
(43) Pub. Date: Mar. 14, 2024

(54) FREQUENCY-TUNABLE FILM BULK ACOUSTIC RESONATOR AND PREPARATION METHOD THEREFOR

(71) Applicant: SOUTH CHINA UNIVERSITY OF TECHNOLOGY, Guangzhou (CN)

(72) Inventors: Guoqiang LI, Guangzhou (CN); Tielin ZHANG, Guangzhou (CN); Hongbin LIU, Guangzhou (CN); Xinyan YI, Guangzhou (CN); Lishuai ZHAO, Guangzhou (CN); Peidong OUYANG, Guangzhou (CN)

(73) Assignee: SOUTH CHINA UNIVERSITY OF TECHNOLOGY, Guangzhou (CN)

(21) Appl. No.: 18/274,236

(22) PCT Filed: Oct. 31, 2021
(86) PCT No.: PCT/CN2021/127795

§ 371 Date: Jul. 26, 2023

(30) Foreign Application Priority Data
Dec. 24, 2020 (CN) 202011572983.8

(51) Int. Cl. H03H 9/17; H03H 3/02; H03H 9/02

(52) U.S. Cl. CPC H03H 9/173; H03H 3/02; H03H 9/02031; H03H 9/178; H03H 2003/021; H03H 2009/02204

(57) ABSTRACT

A frequency-tunable film bulk acoustic resonator and a preparation method therefor are provided. The resonator includes a substrate, an air gap, a sandwiched structure formed by electrodes and piezoelectric layers, and an electrode lead-out layer, wherein the substrate is connected to the sandwiched structure formed by the electrodes and the piezoelectric layers, and a connection face of the substrate and the sandwiched structure formed by the electrodes and the piezoelectric layers is recessed towards inside of the substrate to form the air gap; and the electrode lead-out layer is connected to the sandwiched structure formed by the electrodes and the piezoelectric layers. The sandwiched structure formed by the electrodes and the piezoelectric layers includes a bottom electrode, piezoelectric layers, intermediate electrodes, and a top electrode, wherein the electrodes and the piezoelectric layers are alternately arranged to form the sandwiched structure.

### CROSS REFERENCE TO THE RELATED APPLICATIONS

This application is the national phase entry of International Application No. PCT/CN2021/127795, filed on Oct. 31, 2021, which is based upon and claims priority to Chinese Patent Application No. 202011572983.8, filed on Dec. 24, 2020, the entire contents of which are incorporated herein by reference.

### TECHNICAL FIELD

The present invention relates to the technical field of radio frequency communication, and in particular, to a frequency-tunable film bulk acoustic resonator and a preparation method therefor.

### BACKGROUND

The film bulk acoustic filter is widely applied to front-end signal processing of radio frequency communication, and is an optimal filter device for high-frequency communication, particularly 5G communication, sub-6G communication, and future higher-frequency communication. The bulk acoustic filter plays a crucial role in the processing of radio frequency signals. The bulk acoustic filter has gradually replaced surface acoustic wave devices as a mainstream filter, for example in communication base stations, WiFi routers, and personal mobile portable devices.

The conventional film bulk acoustic resonator is a sandwiched structure formed by an upper layer of metal electrode, a lower layer of metal electrode, and piezoelectric film materials clamped between the upper layer of metal electrode and the lower layer of metal electrode. The principle of the film bulk acoustic resonator is to use a piezoelectric effect, which is that when the dielectric medium is deformed by external force along a certain direction, the polarization phenomenon is generated in the dielectric medium, and simultaneously, charges with opposite positive and negative polarities are generated on two opposite surfaces of the dielectric medium. When an alternating voltage is applied to two end electrodes, the piezoelectric effect makes the piezoelectric film generate mechanical vibration and generate bulk acoustic waves. When a frequency of the acoustic waves and a thickness of the piezoelectric film satisfy a certain mathematical relationship, a resonance phenomenon occurs, and the principle of the bulk acoustic resonator is that the resonance phenomenon under a specific frequency is used to make frequency selection.

For a transmission form of the acoustic wave in the piezoelectric film, specifically, when the bulk acoustic wave is transmitted to an electrode interface, the acoustic wave is reflected back through an acoustic reflection layer outside the electrode, so that the bulk acoustic wave is limited between the two electrodes to generate oscillation. Since the acoustic impedance of air is approximately zero, there is a very strong ability to reflect acoustic waves at a solid/gas interface composed of the electrode material and air. After the filling layer is prepared below the electrode, a cavity is formed to enable a lower electrode to be directly contacted with air, or a part of a substrate of a device is directly etched, so that the lower electrode of the device is suspended to form a solid/gas interface, namely a silicon-etched device.

The frequency-tunable bulk acoustic filter is rarely studied, and most of the filters perform frequency compensation according to temperature changes or modify a mass loading layer above an electrode to tune a resonance frequency. For example, the Chinese Patent Application No. CN202010013002.X entitled “METHOD FOR TUNING RESONATOR FREQUENCY IN BULK ACOUSTIC FILTER AND BULK ACOUSTIC FILTER” and filed by Rofs Microsystem (Tianjin) Co., Ltd. provides that a center frequency of a resonator is tuned by adjusting an area of a mass loading layer above the bulk acoustic resonator. Although the foregoing technology functions as frequency tuning, the frequency tuning is disposable, that is, the frequency is fixed after the device is processed, and thus the frequency cannot be tuned again. This does not solve an essential problem of frequency tuning, cannot implement a function that the frequency of a single resonator changes along with the external single variable, and can only be used as a technical means for frequency modification.

### SUMMARY

To overcome the defects in the conventional technology, an objective of the present invention is to provide a frequency-tunable film bulk acoustic resonator and a preparation method therefor.

The present invention aims to provide a novel frequency-tunable film bulk acoustic resonator and a preparation method therefor. The manufacturing process using the preparation method is simple, the space limitation of the conventional bulk acoustic filter can be broken through, the function which can be implemented by a plurality of bulk acoustic resonators in the past can be implemented by one resonator, the space resource is saved to a greater extent, and the miniaturization progress of the device is promoted.

The objective of the present invention is implemented by one of the following technical solutions.

The frequency-tunable film bulk acoustic resonator provided by the present invention is an air-gap type film bulk acoustic resonator.

The frequency-tunable film bulk acoustic resonator provided by the present invention has a multilayer structure of electrode-piezoelectric layer-electrode-piezoelectric layer-electrode. The composite “sandwiched” structure of the electrodes and piezoelectric layers can be from 1 order to N order. All the electrode layers control the resonance frequency of the resonator through the leading-out layer and the application of a bias voltage (an external bias voltage).

The frequency-tunable film bulk acoustic resonator provided by the present invention comprises: a substrate, an air gap, a sandwiched structure formed by electrodes and piezoelectric layers, and an electrode lead-out layer, wherein the substrate is connected to the sandwiched structure formed by the electrodes and the piezoelectric layers, and a connection face of the substrate and the sandwiched structure formed by the electrodes and the piezoelectric layers is recessed towards inside of the substrate to form the air gap; the electrode lead-out layer is connected to the sandwiched structure formed by the electrodes and the piezoelectric layers; the sandwiched structure formed by the electrodes and the piezoelectric layers comprises a bottom electrode, piezoelectric layers, intermediate electrodes, and a top electrode, wherein the electrodes and the piezoelectric layers are alternately arranged to form the sandwiched structure, the piezoelectric layers are stacked on the bottom electrode, the intermediate electrodes are covered by the piezoelectric layers, and the top electrode is stacked on the piezoelectric layers; and n piezoelectric layer(s) and n intermediate electrode(s) are provided, n is an integer, and n≥1.

The sandwiched structure formed by the electrodes and the piezoelectric layers may comprise a plurality of electrode layers and piezoelectric layers, and the electrode layers and the piezoelectric layers are arranged alternately to form a sandwiched structure together.

The air gap is prepared between the substrate and a lower electrode. The electrode lead-out layer leads out the lower electrode (bottom electrode) and the intermediate electrode. The top electrode, the piezoelectric film, the intermediate electrode, and the bottom electrode form a sandwiched structure together, the resonance frequency multiplication of the resonator can be tuned based on an external bias voltage, and the resonator is applied to the field of 5G high-frequency communications.

Further, both the bottom electrode and the intermediate electrodes of the sandwiched structure formed by the electrodes and the piezoelectric layers are connected to an external bias voltage source through the electrode lead-out layer.

Further, potentials of different electrodes in the sandwiched structure formed by the electrodes and the piezoelectric layers are set to be a same polarity or opposite polarities. Each electrode layer is connected to an external bias voltage source via an electrode lead-out layer, and a potential of each electrode layer can be a same polarity or opposite polarities. That is, the potential difference between all the electrodes may be equal, or the electric fields in the two adjacent piezoelectric layer regions are opposite in direction, as shown in FIGS. 9 and 10.

Further, the substrate is monocrystalline Si; the piezoelectric layer is a piezoelectric film, the piezoelectric layer is more than one of PZT, AlN, ZnO, CdS, and LiNbO₃; the bottom electrode, the intermediate electrode, and the top electrode are all metal electrode layers, and the metal electrode layer is more than one of Pt, Mo, W, Ti, Al, Au, and Ag.

Further, the piezoelectric layer has a thickness of 500 nm to 3 μm; and the top electrode, the intermediate electrode, and the bottom electrode have a thickness of 20 nm to 1 μm.

Further, the electrode lead-out layer has a thickness of 0.3 to 1 μm.

Further, the air gap has a depth of 0.5 to 2 μm.

The present invention provides a preparation method of the frequency-tunable film bulk acoustic resonator, comprising the following steps:
(1) etching the substrate to obtain a groove (an etching mode can use ICP or RIE and other technologies to obtain a groove on the monocrystalline Si substrate), and depositing SiO₂ in the groove as a filling layer (a support layer);
(2) performing mechanical polishing treatment on the filling layer in the step (1) to enable a step between a filling layer region and a surrounding region to be as small as possible, depositing a metal electrode on the filling layer, and performing graphical processing to obtain the bottom electrode (a lower electrode);
(3) depositing n piezoelectric layer(s), n intermediate electrode(s), and a top electrode on the bottom electrode in the step (2), wherein n is an integer and n≥1 (n can be set based on a design requirement, and a multilayer sandwiched structure of “electrode-piezoelectric layer-electrode” may be obtained by depositing the electrodes and the piezoelectric layers for multiple times), the electrodes and the piezoelectric layers are alternated, and the bottom electrode, the piezoelectric layers, the intermediate electrodes, and the top electrode form a sandwiched structure to obtain the sandwiched structure formed by the electrodes and the piezoelectric layers;
(4) after the last layer of top electrode is prepared, etching through holes led out by the electrodes on the piezoelectric layers by using a mask or a photoetching method and depositing the metal to obtain the electrode lead-out layer; and
(5) etching the through holes communicated with the filling layer below by using ICP, RIE, wet etching, or the like, and releasing the filling layer to obtain an air gap (namely an air cavity structure, wherein the filling layer can be released by using an etching solution), thereby obtaining the frequency-tunable film bulk acoustic resonator.

Further, the method for depositing SiO₂ in the step (1) is PECVD (plasma enhanced chemical vapor deposition); the method for depositing the metal electrode in the step (2) is magnetron sputtering or evaporation; and the method for depositing the piezoelectric layers in the step (3) comprises more than one of PVD (physical vapor deposition), MOCVD (metal-organic chemical vapor deposition), PLD (pulsed laser deposition), and ALD (atomic layer deposition).

Further, in the step (4), the method for etching the through holes led out by the electrodes on the piezoelectric layers is to use mask etching or photoetching; the mask is made of SiO₂ or photoresist; and the method for depositing the metal to obtain the electrode lead-out layer is evaporation or magnetron sputtering.

Compared with the prior art, the present invention has the following advantages and beneficial effects:

(1) The present invention aims to provide a novel frequency-tunable film bulk acoustic filter structure, this structure can change the center frequency of a resonator by adjusting an external bias voltage; when the bias voltages applied to the electrodes all have the same magnitude and polarity, the equivalent piezoelectric coupling coefficient signs inside the piezoelectric films in all parts are uniform, so that the resonator resonates at a fundamental resonance frequency f₀ thereof; when the bias voltages applied to the electrodes have the same magnitude and opposite polarities, the equivalent piezoelectric coupling coefficients in the corresponding piezoelectric films are also affected, consequently, the phases of the transmission of the acoustic waves in the piezoelectric films are opposite, and the resonance frequency is changed accordingly.

(2) The frequency-tunable film bulk acoustic resonator provided by the present invention can implement a function that is completed by a plurality of film bulk acoustic resonators in the conventional technology, which saves a space resource and is beneficial to promoting the miniaturization process of devices. The preparation process is simple, the production cost is saved to a great extent, and the preparation process is compatible with the existing MEMS/Si process.

### BRIEF DESCRIPTION OF THE DRAWINGS

FIG. 1 is a sectional view of an air cavity groove etched in a monocrystalline silicon substrate according to Embodiment 1;

FIG. 2 is a sectional view of the groove filled with SiO₂ and polished flat according to Embodiment 1;

FIG. 3 is a sectional view of growing a metal bottom electrode on a monocrystalline silicon substrate according to Embodiment 1;

FIG. 4 is a sectional view of growing a piezoelectric film according to Embodiment 1;

FIG. 5 is a sectional view of growing a metal intermediate electrode according to Embodiment 1;

FIG. 6 is a sectional view showing that a piezoelectric film is continuously grown on an intermediate electrode according to Embodiment 1;

FIG. 7 is a sectional view of growing a top electrode and preparing an electrode lead-out layer according to Embodiment 1;

FIG. 8 is a sectional view showing an air cavity formed by releasing a filling layer below a bottom electrode according to Embodiment 1;

FIG. 9 is a schematic diagram of the frequency-tunable film bulk acoustic resonator provided in Embodiment 1 with a same polarity of bias voltage;

FIG. 10 is a schematic diagram of the frequency-tunable film bulk acoustic resonator provided in Embodiment 1 with opposite polarities of bias voltage;

FIG. 11 is a schematic diagram of an admittance of the frequency-tunable film bulk acoustic resonator provided in Embodiment 1; and

in the drawings, a monocrystalline silicon substrate 101, a filling layer 102, a bottom electrode 103, a piezoelectric film 104, an intermediate electrode 105, an electrode lead-out layer 106, an air cavity 107, and a top electrode 108 are included.

### DETAILED DESCRIPTION OF THE EMBODIMENTS

Specific embodiments of the present invention are further described below with reference to examples, to which, however, the practice and protection of the present invention are not limited. It should be noted that processes not specifically described below can be implemented or understood by those skilled in the art with reference to the prior art. Reagents or instruments without specified manufacturers used herein are conventional products that are commercially available.

An example of the present invention provides a method for tuning a film bulk acoustic filter. Tuning a frequency of a film bulk acoustic filter that is commonly used in the art is implemented by adjusting a thickness or an area of a mass loading layer above the top electrode. In this example, a novel resonator structure is provided to implement frequency multiplication tuning of the film bulk acoustic filter.

### Embodiment 1

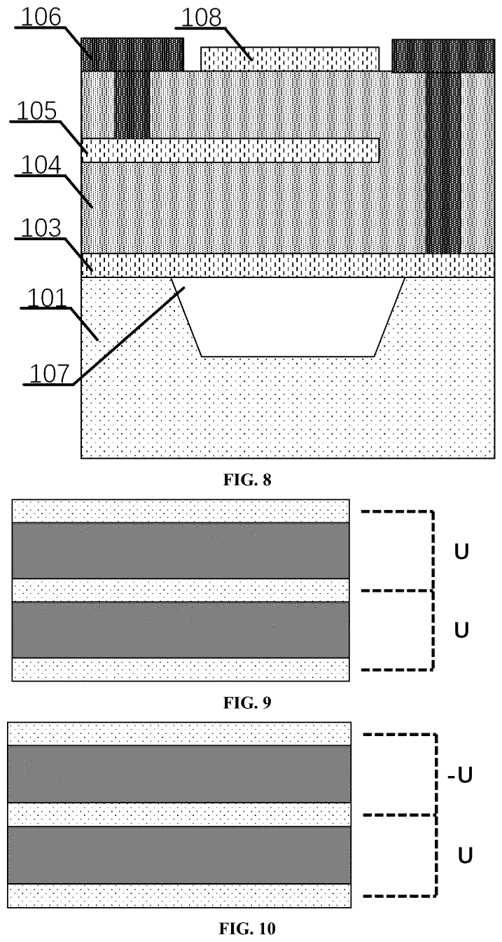

This embodiment provides a frequency-tunable air-gap type film bulk acoustic resonator, as shown in FIG. 8, which comprises: a monocrystalline silicon substrate 101, a filling layer 102, a bottom electrode 103, a piezoelectric film 104 (a piezoelectric layer), an intermediate electrode 105, an electrode lead-out layer 106, an air cavity 107, and a top electrode 108 from bottom to top. The filling layer 102 is finally released to form an air cavity 107 (air gap), so that the filling layer 102 is not shown in the drawings. For a specific structure of the filling layer 102, refer to FIG. 2.

The frequency-tunable air-gap type film bulk acoustic resonator provided by Embodiment 1 comprises: a monocrystalline silicon substrate 101, an air gap 107, a sandwiched structure formed by electrodes and piezoelectric layers, and an electrode lead-out layer 106, wherein the substrate is connected to the sandwiched structure formed by the electrodes and the piezoelectric layers, and a connection face of the monocrystalline silicon substrate 101 and the sandwiched structure formed by the electrodes and the piezoelectric layers is recessed towards inside of the substrate to form the air gap 107; the electrode lead-out layer 106 is connected to the sandwiched structure formed by the electrodes and the piezoelectric layers; the sandwiched structure formed by the electrodes and the piezoelectric layers comprises a bottom electrode 103, piezoelectric layers 104, intermediate electrodes 105, and a top electrode 108, wherein the electrodes and the piezoelectric layers are alternately arranged to form the sandwiched structure, the piezoelectric layers 104 are stacked on the bottom electrode 103, the intermediate electrodes 105 are covered by the piezoelectric layers 104, and the top electrode 108 is stacked on the piezoelectric layers 104; and n piezoelectric layer(s) 104 and n intermediate electrode(s) 105 are provided, n is an integer, and n≥1.

The substrate 101 is monocrystalline silicon Si; the filling layer 102 is SiO₂ or P ion-doped SiO₂; the piezoelectric film 104 is AlN with a thickness of 0.5 μm; the bottom electrode 103, the top electrode 108, and the intermediate electrode 105 are all metal electrode layers with a thickness of 200 nm, and the metal is Mo.

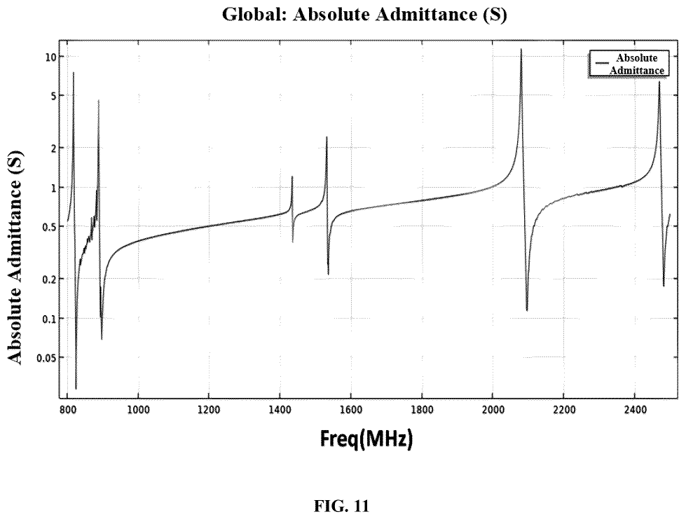

In addition to the top electrode, each electrode layer is connected to an external bias voltage source via an electrode lead-out layer, and a potential of each electrode layer can be a same polarity or opposite polarities. That is, the potential difference between all the electrodes may be equal, or the electric fields in the two adjacent piezoelectric layer regions are opposite in direction, as shown in FIGS. 9 and 10. U in FIGS. 9 and 10 represents an external bias voltage applied to the electrodes.

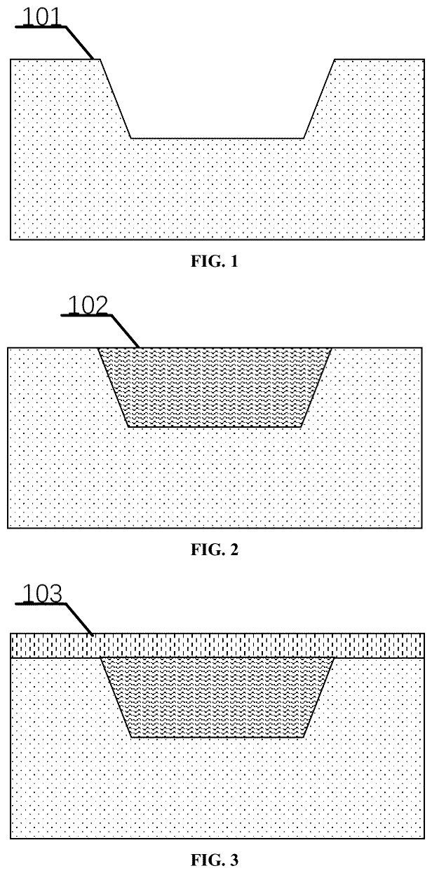

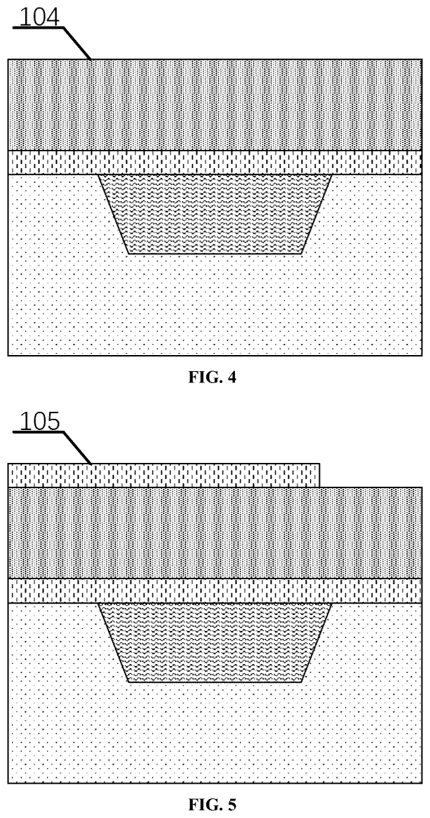

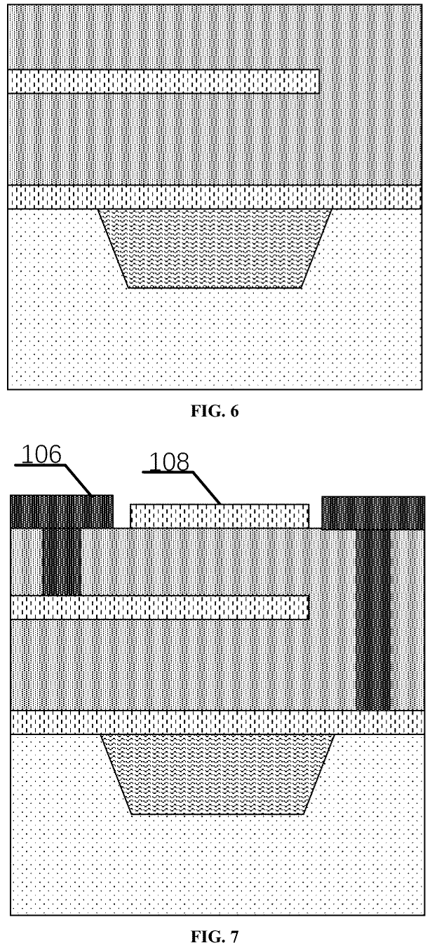

In Embodiment 1, the frequency-tunable air-gap type film bulk acoustic resonator is prepared by the following steps:
(1) etching the monocrystalline silicon substrate 101 (an etching mode can use ICP or RIE and other technologies to obtain a groove on the monocrystalline Si substrate), wherein the groove has a depth of 2 μm, as shown in FIG. 1;
(2) depositing SiO₂ as a filling layer 102 (shown in FIG. 2) in the groove by using the PECVD technology and other technologies, and using chemical mechanical polishing to obtain a surface with a step smaller than 20 nm on the filling layer 102 and the Si surface of the surrounding region; and depositing a metal electrode on the filling layer, and performing graphical processing to obtain a bottom electrode 103 (shown in FIG. 3), wherein the material of the bottom electrode (lower electrode) 103 is metal Mo, and the electrode has a thickness of 0.2 μm;
(3) depositing n piezoelectric layer(s) 104 (shown in FIG. 4, and only one piezoelectric layer is depicted in FIG. 4 but a plurality of piezoelectric layers can be formed in the actual production process), n intermediate electrode(s) 105 (shown in FIG. 5, and only one intermediate electrode is depicted in FIG. 5 but a plurality of intermediate electrodes can be formed in the actual production process), and a top electrode 108 on the bottom electrode 103 in the step (2), wherein n is an integer and n≥1, the electrodes and the piezoelectric layers are alternated, and the bottom electrode 103, the piezoelectric layers 104, the intermediate electrodes 105, and the top electrode 108 form a sandwiched structure to obtain the sandwiched structure, the intermediate electrodes are covered by the piezoelectric layers (as shown in FIG. 6), and the top electrode is stacked on the piezoelectric layers (as shown in FIG. 7), so that the sandwiched structure formed by the electrodes and the piezoelectric layers is obtained; the piezoelectric layer 104 may be made of AlN, with a piezoelectric layer thickness of 2 μm; the thickness of the intermediate electrodes 105 is 0.2 μm; the area of the top electrode 108 is smaller than that of the bottom electrode 103, and the thickness of the top electrode is 0.2 μm;
(4) after the top electrode is prepared, etching through holes led out by the electrodes on the piezoelectric layers 104 by using a mask or a photoetching method and depositing the metal to obtain the electrode lead-out layer 106, as shown in FIG. 7; and
(5) etching the through holes communicated with the filling layer 102 by using ICP, RIE, wet etching, or the like, and releasing the filling layer 102 by using an etching solution to form an air cavity 107 structure (air gap), thereby obtaining the frequency-tunable film bulk acoustic resonator (as shown in FIG. 8).

In an example, Embodiment 1 obtains the frequency-tunable film bulk acoustic resonator, wherein both the number of piezoelectric film layers and the number of intermediate electrodes are 2, that is, n is 2. When n is equal to 2, the obtained frequency-tunable film bulk acoustic resonator is subjected to a filter admittance test, which is performed by a network analyzer Anglent E50. The testing process is to connect the network analyzer with a probe station, and fix the wafer and the probe on the probe station. Then, the network analyzer is calibrated, and the center frequency of the network analyzer is set to 1675 MHz, and the tested bandwidth is 900 MHz. The probe station is moved to enable the probe to contact the metal electrode on the surface of the wafer, and a scanning test is performed by using a scanning key. As shown in FIG. 11, when the bias voltage applied to the electrodes is changed, the resonator presents different resonance peaks, which indicates: the piezoelectric coupling coefficient is affected by the bias voltage, and the resonance frequency is changed accordingly.

According to the same principle, the bulk acoustic resonator of this embodiment can deduce that when the number of the piezoelectric film layers is 1, 2, 3 . . . N (N is a positive integer), and the value of N is increased continuously, the resonance frequency of the bulk acoustic resonator can be multiplied.

The foregoing embodiment is only a preferred embodiment of the present invention, and is merely intended to illustrate but not to limit the present invention. The changes, replacements, and modifications made by those skilled in the art without departing from the spirit and essence of the present invention shall fall within the protection scope of the present invention.

What is claimed is:

1. A frequency-tunable film bulk acoustic resonator, comprising: a substrate, an air gap, a sandwiched structure formed by electrodes and piezoelectric layers, and an electrode lead-out layer, wherein the substrate is connected to the sandwiched structure formed by the electrodes and the piezoelectric layers, and a connection face of the substrate and the sandwiched structure formed by the electrodes and the piezoelectric layers is recessed towards an inside of the substrate to form the air gap; the electrode lead-out layer is connected to the sandwiched structure formed by the electrodes and the piezoelectric layers; the sandwiched structure formed by the electrodes and the piezoelectric layers comprises a bottom electrode, the piezoelectric layers, intermediate electrodes, and a top electrode, wherein the electrodes and the piezoelectric layers are alternately arranged to form the sandwiched structure, the piezoelectric layers are stacked on the bottom electrode, the intermediate electrodes are covered by the piezoelectric layers, and the top electrode is stacked on the piezoelectric layers; and n piezoelectric layer(s) and n intermediate electrode(s) are provided, n is an integer, and n≥1.

2. The frequency-tunable film bulk acoustic resonator according to claim 1, wherein the bottom electrode and the intermediate electrodes of the sandwiched structure formed by the electrodes and the piezoelectric layers are connected to an external bias voltage source through the electrode lead-out layer.

3. The frequency-tunable film bulk acoustic resonator according to claim 1, wherein potentials of different electrodes in the sandwiched structure formed by the electrodes and the piezoelectric layers are set to be a same polarity or opposite polarities.

4. The frequency-tunable film bulk acoustic resonator according to claim 1, wherein the substrate is monocrystalline Si; each of the piezoelectric layers is a piezoelectric film, each of the piezoelectric layers is more than one of PZT, AlN, ZnO, CdS, and LiNbO₃; the bottom electrode, the intermediate electrodes, and the top electrode are metal electrode layers, and each of the metal electrode layers is more than one of Pt, Mo, W, Ti, Al, Au, and Ag.

5. The frequency-tunable film bulk acoustic resonator according to claim 1, wherein each of the piezoelectric layers has a thickness of 500 nm to 3 μm; and each of the top electrode, the intermediate electrodes, and the bottom electrode has a thickness of 20 nm to 1 μm.

6. The frequency-tunable film bulk acoustic resonator according to claim 1, wherein the electrode lead-out layer has a thickness of 0.3 to 1 μm.

7. The frequency-tunable film bulk acoustic resonator according to claim 1, wherein the air gap has a depth of 0.5 to 2 μm.

8. A preparation method of the frequency-tunable film bulk acoustic resonator according to claim 1, comprising the following steps:
(1) etching the substrate to obtain a groove, and depositing SiO₂ in the groove as a filling layer;
(2) depositing a metal electrode on the filling layer in step (1), and performing a graphical processing to obtain the bottom electrode;
(3) depositing then piezoelectric layer(s), then intermediate electrode(s), and the top electrode on the bottom electrode in step (2), wherein the electrodes and the piezoelectric layers are alternated, and the bottom electrode, the piezoelectric layers, the intermediate electrodes, and the top electrode form the sandwiched structure to obtain the sandwiched structure formed by the electrodes and the piezoelectric layers;
(4) etching through holes led out by the electrodes on the piezoelectric layers and depositing a metal to obtain the electrode lead-out layer; and
(5) etching the through holes communicated with the filling layer below and releasing the filling layer to obtain the air gap to obtain the frequency-tunable film bulk acoustic resonator.

9. The preparation method of the frequency-tunable film bulk acoustic resonator according to claim 8, wherein a method for depositing the SiO₂ in step (1) is plasma enhanced chemical vapor deposition (PECVD); a method for depositing the metal electrode in step (2) is a magnetron sputtering or an evaporation; and a method for depositing the piezoelectric layers in step (3) comprises more than one of physical vapor deposition (PVD), metal-organic chemical vapor deposition (MOCVD), pulsed laser deposition (PLD), and atomic layer deposition (ALD).

10. The preparation method of the frequency-tunable film bulk acoustic resonator according to claim 8, wherein in step (4), a method for etching the through holes led out by the electrodes on the piezoelectric layers is to use a mask etching or a photoetching; a mask is made of SiO₂ or a photoresist; and a method for depositing the metal to obtain the electrode lead-out layer is an evaporation or a magnetron sputtering.

11. The preparation method of the frequency-tunable film bulk acoustic resonator according to claim 8, wherein the bottom electrode and the intermediate electrodes of the sandwiched structure formed by the electrodes and the piezoelectric layers are connected to an external bias voltage source through the electrode lead-out layer.

12. The preparation method of the frequency-tunable film bulk acoustic resonator according to claim 8, wherein potentials of different electrodes in the sandwiched structure formed by the electrodes and the piezoelectric layers are set to be a same polarity or opposite polarities.

13. The preparation method of the frequency-tunable film bulk acoustic resonator according to claim 8, wherein the substrate is monocrystalline Si; each of the piezoelectric layers is a piezoelectric film, each of the piezoelectric layers is more than one of PZT, AlN, ZnO, CdS, and LiNbO₃; the bottom electrode, the intermediate electrodes, and the top electrode are metal electrode layers, and each of the metal electrode layers is more than one of Pt, Mo, W, Ti, Al, Au, and Ag.

14. The preparation method of the frequency-tunable film bulk acoustic resonator according to claim 8, wherein each of the piezoelectric layers has a thickness of 500 nm to 3 μm; and each of the top electrode, the intermediate electrodes, and the bottom electrode has a thickness of 20 nm to 1 μm.

15. The preparation method of the frequency-tunable film bulk acoustic resonator according to claim 8, wherein the electrode lead-out layer has a thickness of 0.3 to 1 μm.

16. The preparation method of the frequency-tunable film bulk acoustic resonator according to claim 8, wherein the air gap has a depth of 0.5 to 2 μm.
